(19) United States
(12) Patent Application Publication
(10) Pub. No.: US 2024/0159960 A1
(43) Pub. Date: May 16, 2024

(54) HETEROGENEOUSLY INTEGRATED ILLUMINATOR

(71) Applicant: Nexus Photonics, Inc., Goleta, CA (US)

(72) Inventors: Tin KOMLJENOVIC, Goleta, CA (US); Charles ROXLO, Saratoga, CA (US)

(73) Assignee: Nexus Photonics, Inc., Goleta, CA (US)

(21) Appl. No.: 17/988,636

(22) Filed: Nov. 16, 2022

(51) Int. Cl. G02B 6/12; G02B 6/125; H01S 5/02253; H01S 5/068

(52) U.S. Cl. CPC G02B 6/12004; G02B 6/125; H01S 5/02253; H01S 5/068; G02B 2006/12102; G02B 2006/12121

(57) ABSTRACT

A device comprises at least one of first, second and third elements fabricated on a common substrate. At least one of the first elements comprises an active waveguide structure and optical sources supporting an active optical mode and defined by at least one etch after attachment to the common substrate. At least one of the second elements comprises a passive waveguide structure supporting a passive optical mode, also comprising at least one of the one splitter structure and two emitter structures. At least one of the third elements, at least partly butt-coupled to at least one of the first elements, comprises an intermediate waveguide structure supporting intermediate optical modes. Mutual alignments of the first, second and third elements are defined using lithographic alignment marks that facilitate precise alignment between layers formed during processing steps of fabricating the first, the second and the third elements on a common substrate.

### FIELD OF THE INVENTION

The present invention relates to photonic integrated circuits. More specifically, certain embodiments of the invention relate to improved performance of heterogeneously integrated illuminators and related components with improved performance.

### BACKGROUND OF THE INVENTION

A photonic integrated circuit (PIC) or integrated optical circuit is a device that integrates multiple photonic functions and as such is analogous to an electronic integrated circuit. The major difference between the two is that a photonic integrated circuit provides functions imposed on optical carrier waves. A photonic integrated circuit can also generate light with advanced properties in one chip. The material platform most commercially utilized for photonic integrated circuits is indium phosphide (InP), which allows for the integration of various optically active and passive functions on the same chip. Although many current PICs are realized in InP platforms, there has been significant research in the past decade in using silicon rather than InP for the realization of PICs, due to some superior characteristics as well as superior processing capabilities for the former material, that leverage the investment already made for electronic integrated circuits.

The biggest drawback in using silicon for PICs is that it is an indirect bandgap material which makes it hard to provide electrically pumped sources. This problem is generally solved by assembling PICs comprising two or more chips made from dissimilar materials in separate processes. Such an approach is challenging due to a need for very fine alignment, which increases packaging costs and introduces scaling limitations. Another approach to solving the bandgap problem is to bond two dissimilar materials and process them together, removing the need for precise alignment during the bonding of larger pieces or complete wafers of the dissimilar materials, and allowing for mass fabrication. In this disclosure, we use the term “hybrid” to describe the first approach that includes precise assembly of separately processed parts, and we use the term “heterogeneous” to describe the latter approach of bonding two materials and then processing the bonded result to define the waveguides and other components of interest.

To transfer the optical signal between dissimilar materials, the heterogeneous approach utilizes tapers whose dimensions are gradually reduced until the effective mode refractive indexes of dissimilar materials match and there is efficient power transfer. This approach generally works well when materials have small difference in refractive indexes as is the case with silicon and InP. In cases where there is larger difference in effective indexes, such as between e.g. SiN and GaAs or InP, the requirements on taper tip dimensions become prohibitive limiting efficient power transfer. Specifically, extremely small taper tip widths (of the order of tens of nanometers) may be necessary to provide good coupling. Achieving such dimensions is complex and may be cost prohibitive.

Although InP and silicon-based PICs address many current needs, they have some limitations; among them the fact that the operating wavelength range is limited by material absorption increasing the losses, lower thermal stability and the fact that there is a limit on the maximum optical intensities and consequently optical powers that a PIC can handle. To address these limitations, alternate waveguide materials have been considered, such as SiN, SiNOx, LiNbO₃, TiO₂, Ta₂O₅, AlN or others. In general, such dielectric waveguides have higher bandgap energies which provides better high-power handling and transparency at shorter wavelength, but, in general such materials also have lower refractive indexes. E.g. SiN with bandgap of ˜5 eV has refractive index of ˜2, AlN has bandgap of ˜6 eV and refractive index of around ˜2, and SiO₂ with bandgap of ˜8.9 eV has refractive index of ˜1.44. For comparison, the refractive index of both InP and GaAs is >3. This makes the tapered approach challenging.

The alternative hybrid approach suffers from the drawbacks already mentioned above, namely the need for precise alignment, and correspondingly complex packaging and scaling limitations.

A recent approach to the problems discussed above was presented in U.S. Pat. No. 10,859,764 B2 employing butt-coupling in combination with a mode-converter to allow the heterogenous process to be used without the need for extremely small taper widths.

Here we describe a heterogeneously integrated illuminator and related components with improved performance that leverages benefits of using dissimilar materials for improved performance. Compared to prior approaches, the heterogeneously integrated illuminator enables operation in ultrabroadband wavelength range from as short as ultraviolet (UV) to as long as mid-infrared (MIR) and beyond utilizing widely transparent materials and waveguides to guide, split and shape the light, and utilizes state-of-the-art direct electrically-pumped semiconductor sources, amplifiers, modulators and detectors. The use of waveguide materials that can be precisely patterned, etched and (re)deposited enables significantly higher performance of the light shaping elements such as surface emitting structures further improving the performance compared to current assembled systems mostly utilizing vertical-cavity surface-emitting lasers (VSCELs) or edge-emitting lasers with corner reflector structures or similar. Furthermore, the ability to control the intensity of particular sub-set of the emitters, as will be described below, enables higher uniformity of the illuminator leading to further improvement of the performance.

Finally, fully integrated with on-chip sources enables additional size, weight and power reduction, as well as reduced cost at scale due to wafer-scale manufacturing and testing enabled by the heterogeneous integration.

The present invention is directed towards improving the state-of-the-art of the illuminators realized as heterogeneously integrated PICs. In particular, embodiments described below are concerned with the detailed design of the PIC architecture, individual components and optical coupling structure between waveguides and active components necessary for creation of high-performance illuminators for next generation of sensors in various fields including, but not limited to, augmented reality (AR), virtual Reality (VR), machine vision, general perception systems, light detection and ranging (LIDAR), healthcare and light-sciences and beyond.

### BRIEF DESCRIPTION OF THE DRAWINGS

FIG. 1 illustrates a device according to one embodiment of the present invention, shown in top-view.

FIG. 2 shows three embodiments of devices according to some embodiments of the present invention shown in top-view.

FIGS. 3a and 3b shows two embodiments of devices according to some embodiments of the present invention shown in top-view.

FIG. 4 shows one embodiment of a device according to some embodiments of the present invention shown in top-view.

FIG. 5 illustrates three embodiments of devices according to some embodiments of the present invention, shown in cross section.

FIG. 6 illustrates four embodiments of devices according to some embodiments of the present invention, shown in top-view.

FIG. 7 illustrates a device according to one embodiment of the present invention, shown in cross section.

FIG. 8 illustrates four embodiments of devices according to some embodiments of the present invention, shown in top-view.

FIG. 9 illustrates embodiments of a device, shown in top-views and in cross section.

### DETAILED DESCRIPTION

Described herein include embodiments of a heterogeneously integrated illuminator and related components with improved performance leveraging dissimilar materials to improve the functionality, performance and reduce size, weight, and cost.

In the following detailed description, reference is made to the accompanying drawings which form a part hereof, wherein like numerals designate like parts throughout, and in which are shown by way of illustration embodiments in which the subject matter of the present disclosure may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

The description may use perspective-based descriptions such as top/bottom, in/out, over/under, and the like. Such descriptions are merely used to facilitate the discussion and are not intended to restrict the application of embodiments described herein to any particular orientation. The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The term “coupled with,” along with its derivatives, may be used herein. “Coupled” may mean one or more of the following. “Coupled” may mean that two or more elements are in direct physical, electrical, or optical contact. However, “coupled” may also mean that two or more elements indirectly contact each other, but yet still cooperate or interact with each other, and may mean that one or more other elements are coupled or connected between the elements that are said to be coupled with each other. The term “directly coupled” means that two or more elements are in direct contact in at least part of their surfaces. The term “butt-coupled” is used herein in its normal sense of meaning an “end-on” or axial coupling, where there is minimal or zero axial offset between the elements in question. The axial offset may be, for example, slightly greater than zero in cases where a thin intervening layer of some sort is formed between the elements, such as e.g. thin coating layer typically used to provide high-reflectivity or anti-reflectivity functionality. It should be noted that the axes of two waveguide structures or elements need not be colinear for them to be accurately described as being butt-coupled. In other words, the interface between the elements need not be perpendicular to either axis in cases e.g. this interface is angled to control the reflections at the interface. No adiabatic transformation occurs between butt-coupled structures/interfaces.

Term “active device”, “active structure” or otherwise “active” element, part, component may be used herein. A device or a part of a device called active is capable of light generation, amplification, modulation and/or detection using electrical contacts. This is in contrast to what we mean by a “passive device” whose principal function is to confine and guide light, and/or provide splitting, combining, filtering and/or other functionalities that are commonly associated with passive devices. Some passive devices can provide functions overlapping with active device functionality, such as e.g. phase tuning implemented using thermal effects or similar that can provide modulation. No absolute distinction should be assumed between “active” and “passive” based purely on material composition or device structure. A silicon device, for example, may be considered active under certain conditions of modulation, or detection of low wavelength radiation, but passive in most other situations.

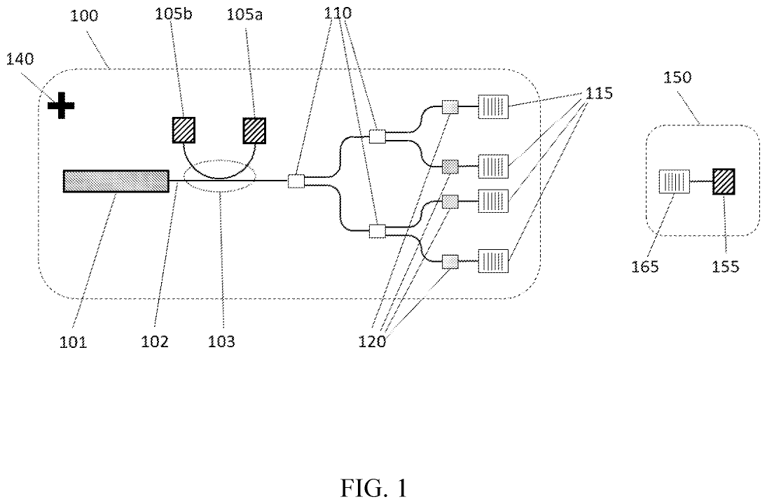

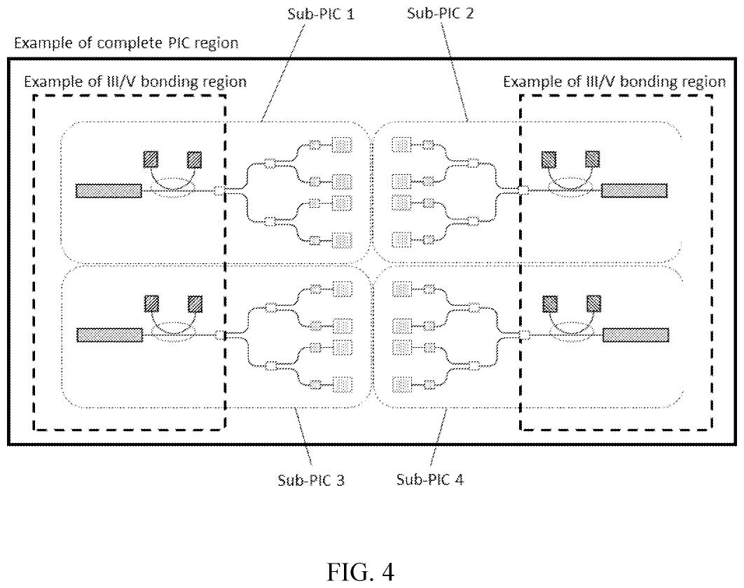

FIG. 1 is a schematic top-view of an integrated photonic device 100 showing one embodiment of an integrated illuminator. In some of the embodiments described below, the integrated illuminator is realized as a PIC including just one optical “unit” of the type 100 shown in FIG. 1 connected to an external electronic unit, while in others, the PIC includes a plurality of similar or identical “units” or “sub-systems”, the plurality sharing a single external electronic unit as will be described with the help of FIG. 4. In some embodiments, integrated illuminator 100 is combined with integrated photonic device 150 enabling distance measurements and/or proximity detection as will be described below.

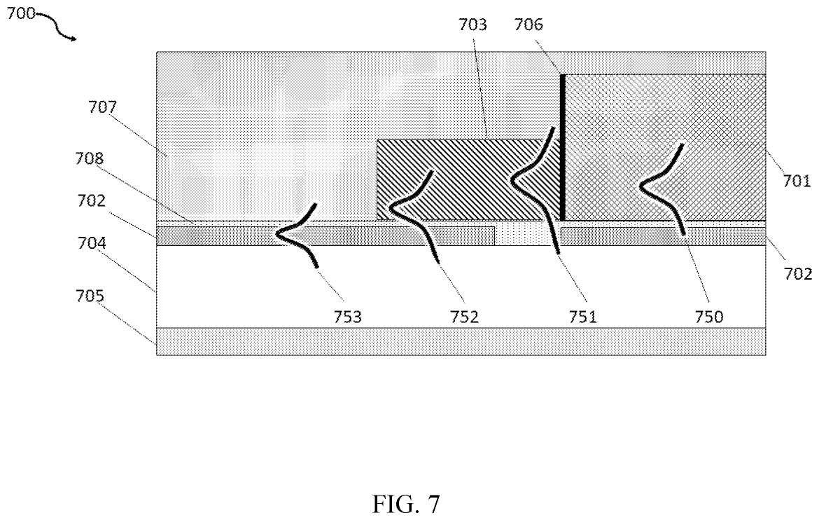

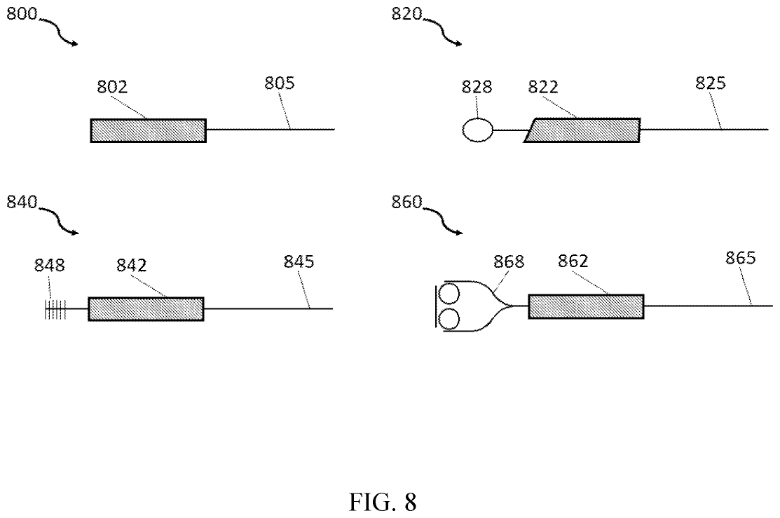

In one embodiment, the integrated illuminator sub-system comprises at least three functional elements 101, 110 and 115 connected with waveguides 102. Element 101 is the optical source providing efficient light generation when injected by current. Optical source 101 can be a Fabry-Perot laser, single-frequency laser, wavelength-stabilized laser, tunable laser, broadband optical source, and/or other suitable optical sources with additional details provided with the help of FIG. 8. Common materials used to realize the optical source depend on the operation wavelength and can include InP and InP-based ternary and quaternary materials, GaAs and GaAs based ternary and quaternary materials, GaN and GaN based ternary and quaternary materials, GaP, InAs and InSb and their variations and derivatives or any other suitable material for providing direct optical emission. Optical source is efficiently coupled to the passive waveguide 102 using butt-coupled assisted structure as described with the help of FIG. 7. At least one of the splitter 110 structures, if present, is utilized to split the incident optical signal into at least two parts. In the embodiment shown in FIG. 1, two layers of splitter 110 structures are utilized to split light into 4 outputs. Examples of splitter structures are directional couplers, adiabatic couplers, Y-junctions, and/or multi-mode interference (MMI) couplers, and or other structures capable of dividing the input optical signal in at least two parts. It is obvious that such splitting can be cascaded to an arbitrary output number. In some embodiments, emitter structures can be spatially touching each other in at least part of the device. Output from splitter structures is then routed to emitter 115 structure that serves to convert the light from in-plane propagation to out-of-plane propagation. Such emitter structure can be grating structures, corner reflectors, slanted and/or bent waveguides. In all cases, the aperture of the emitter 115 is controlled such that the beam shape and direction are optimized for generating the illuminator pattern with satisfactory shape and coverage.

In some embodiments it is important to control the output power of each emitter to be of particular intensity and that all the emitters have as uniform intensity as possible. In such embodiments, the splitter 110 structures are often realized as Y-junction, MMI couplers, and/or a combination of both as they generally provide more uniform power splitting. In other embodiments, power can be varied between emitters by utilizing non-symmetric splitters. A common non-symmetric splitter is a directional coupler or MMI coupler with suitably designed splitting ratio. In yet another embodiment, at least one photodetector 105a is introduced. The purpose of this photodetector is to monitor the output power of the optical source 101 via a tap-coupler 103. Tap coupler is a coupler that typically couples small amount of incident light to the output connected to photodetector 105a while passing most of the incident light to the output connected to the splitter structure. In some embodiments <5% of power is directed towards the photodetector 105a. Signal from photodetector 105a can be utilized to control total power emitted by the optical source 101 and radiated through emitters 115. This can account for both the process variations as well as e.g. impacts of external temperature and/or device aging on the output power of the optical source 101. In yet other embodiments, a second photodetector 105b is introduced. Said detector can be used to monitor the back reflection from the elements of the photonic integrated device, and/or back reflection that is external to the photonic integrated device. In such cases, the functionality can be expanded to provide distance measurements (if source 101 is pulsed or continuously swept) and/or proximity detection. Similar functionality can also be provided using the photonic integrated device 150 that comprises at least one of the emitters 165 configured to receive the optical signal and connected to photodetector 155. In case device 150 is utilized, it will only receive signals that are reflected from objects/elements that are external to the photonic integrated device, in contrast to photodetector 105b that can also detect on-chip reflections.

In yet other embodiments, tuning elements 120 are introduced that provide ability to control amplitude/phase of individual emitter. This can be utilized for more advanced control of the output pattern in terms of power (e.g. amplitude modulation) or enable advanced proximity detection as signals from particular elements can have modulation imprinted which can be efficiently detected on photodetector 105b and/or 155. In other embodiments, said detection can be performed with external camera (not shown).

Alternatively, the architecture shown in view 100 can be used to make a large number of emitters using light originating from a single laser 101. Such an embodiment produces coherent emissions over a large number of emitters and a large area. In combination with the phase and amplitude modulators 120, this can be used to provide beam-steering or shaping, such as focusing of the beam.

Alignment mark 140 (one shown, but multiple can be utilized) are used to define precise transition between the waveguide 102 and optical source 101, photodetectors 105a, 105b, 155 and/or other active devices as will be described with the help of FIG. 7.

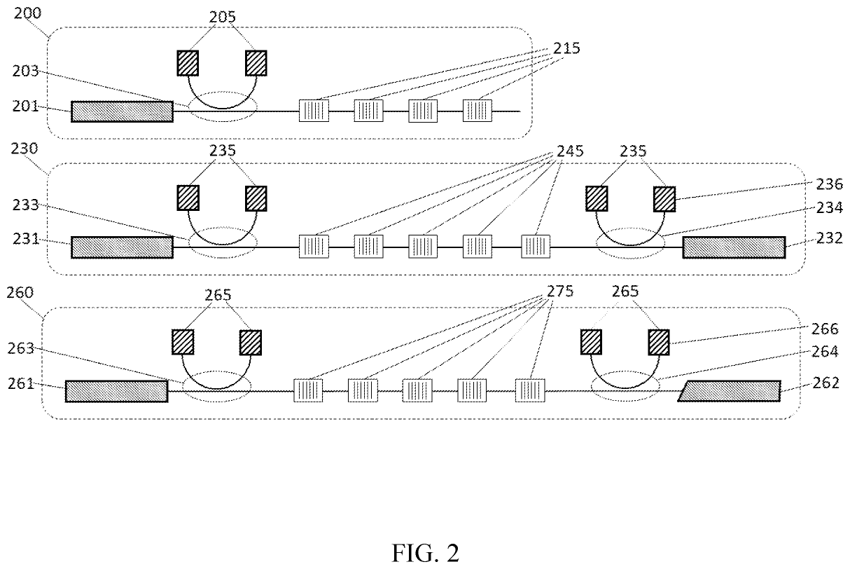

FIG. 2 is a schematic top-view of three embodiments of present invention in which emitters 215, 245 and/or 275 are realized as gratings and are arranged so that they are in-line. In some embodiments, each in-line emitter has optimized grating strength such that output from each of the emitters is substantially similar while accounting for different powers incident to each of the in-line emitters. This can easily be done by adjusting the strength and/or length of the grating to account accordingly for the varying optical powers incident to each emitter. The powers necessarily vary as parts of incident signal are emitted at each emitter point. In other embodiments, the strength of each grating is identical resulting with different output powers. In yet other embodiments, strength of each emitter is optimized such as to achieve the required power distribution for optimal system operation.

In the embodiment shown in view 200, a single optical source 201 is connected to two or more in-line emitters 215, with optional tap coupler 203 and one or more optional photodetectors 205 providing additional functionality related to control of the output power and detecting back reflected signal as described with the help of FIG. 1. Embodiment 200 can be combined with equivalent of the photonic integrated circuit 150 as also described with the help of FIG. 1.

In the embodiment shown in view 230, two optical sources 231 and 232 are connected to two or more in-line emitters 245, with optional tap couplers 233 and 234 and one or more optional photodetectors 235 providing additional functionality related to control of the output power and detecting back reflected signal as described with the help of FIG. 1. Embodiment 230 can be combined with equivalent of the photonic integrated circuit 150 as also described with the help of FIG. 1.

In the embodiment shown in view 260, two optical sources 261 and 262 are connected to two or more in-line emitters 265, with optional tap couplers 263 and 264 and one or more optional photodetectors 265 providing additional functionality related to control of the output power and detecting back reflected signal as described with the help of FIG. 1. In contrast to embodiment shown in view 230 that uses sources as described with the help of FIG. 1, in the case of the embodiment shown in view 260 at least one of the sources is effectively a reflective semiconductor optical amplifier (in shown embodiment source 262 as suggested in FIG. 2 where its input facet is angled). The use of reflective semiconductor optical amplifier enables it to be efficiently seeded by the other optical source (261) while boosting its power. Embodiment 260 can be combined with equivalent of the photonic integrated circuit 150 as also described with the help of FIG. 1.

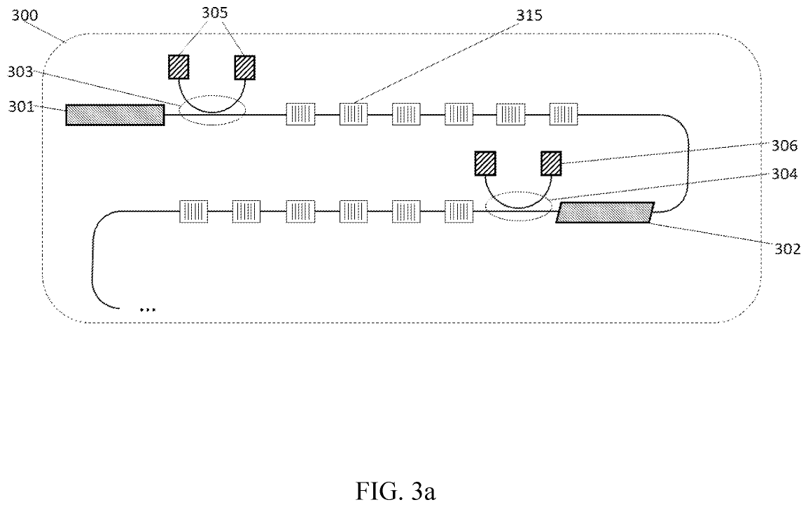

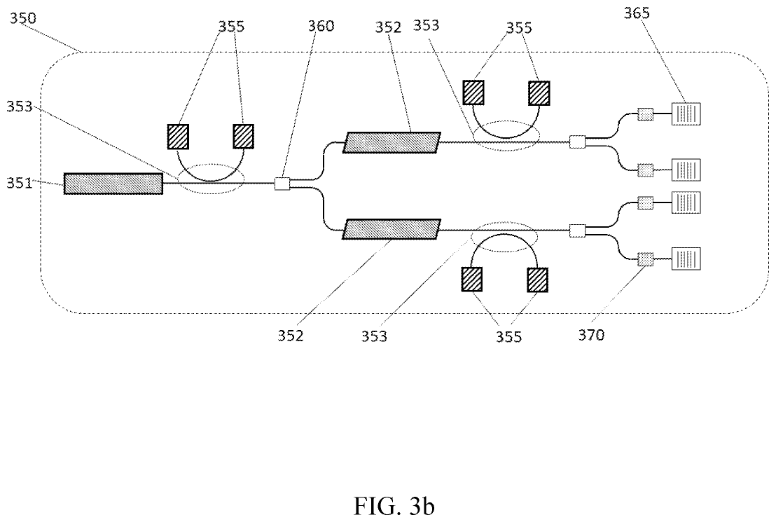

FIGS. 3a and 3b are schematic top-views of two embodiments of present invention. In the embodiment shown in view 300, a single optical source 301 is connected to two or more in-line emitters 315, with optional tap coupler 303 and one or more optional photodetectors 305 providing additional functionality related to control of the output power and detecting back reflected signal as described with the help of FIG. 1. To further increase the output power, after light has been emitted through few (>2) emitters, a semiconductor optical amplifier 302 is introduced to boost the power before continuing the same structure of in-line emitters and optional tap coupler 304 with one or more optional photodetectors 306. The in-line amplification serves both to boost the output power and also regulate the intensity of each sub-group of the emitters. Multiple in-line groups comprising semiconductor optical amplifiers and emitters can be utilized in a particular embodiment. Embodiment 300 can be combined with equivalent of the photonic integrated circuit 150 as also described with the help of FIG. 1.

In the embodiment shown in view 350, a single optical source 351 is connected to two or more emitters 365 via one or more splitter 360 structures, with one or more of optional tap couplers 353 and one or more optional photodetectors 355 providing additional functionality related to control of the output power and detecting back reflected signal as described with the help of FIG. 1. To further increase the output power, after light has been split at least once, one or more of semiconductor optical amplifiers 352 are introduced to boost the power before continuing the same structure of splitters followed by emitters. In yet other embodiments, tuning elements 370 are introduced that provide ability to control amplitude/phase of individual emitter. This can be utilized for more advanced control of the output pattern in terms of power (e.g. amplitude modulation) or enable advanced proximity detection as signals from particular elements can have modulation imprinted which can be efficiently detected on any of suitable photodetectors. Embodiment 350 can be combined with equivalent of the photonic integrated circuit 150 as also described with the help of FIG. 1. In other embodiments, said detection can be performed with external camera (not shown).

Alternatively, the architecture shown in view 350 can be used to make a large number of emitters using light originating from a single laser 351. Such an embodiment produces coherent emissions over a large number of emitters and a large area. In combination with the phase and amplitude modulators 370, this can be used to provide beam-steering or shaping, such as focusing of the beam.

FIG. 4 is a schematic top-view of an embodiment of integrated photonic device comprising a plurality of similar or identical interconnected “units” or “sub-systems”, the plurality sharing the same fabrication process flow as will be described with the help of FIG. 7 and a single external electronic unit (not shown). Any of the embodiments described above can be one of the sub-systems or units combined to form the plurality. Furthermore, different sub-units can be utilized to form the plurality. One of the benefits of forming the complete system from a plurality of sub-units is the ability to independently control each sub-unit resulting with improved power uniformity and improved robustness in the case one of the sub-units fail. Additional benefit is the material cost of fabrication as will be explained here. The total cost of the integrated illuminator is approximately related to the total size of the photonic integrated circuit, and in heterogeneous photonics it is beneficial to simplify the layout such that regions between passive and active components are separated. The cost of passive area is significantly lower than the cost of the active area, and there is cost associated with bonding the III/V material. To optimize the cost, it is then beneficial to arrange the integrated photonic device similarly to the embodiment shown in FIG. 4 where larger areas of passives are combined together, while multiple active regions can share the single bonding step as illustrated with dashed lines in which active material is shared between sub-PICs 1 and 3, and between sub-PICs 2 and 4.

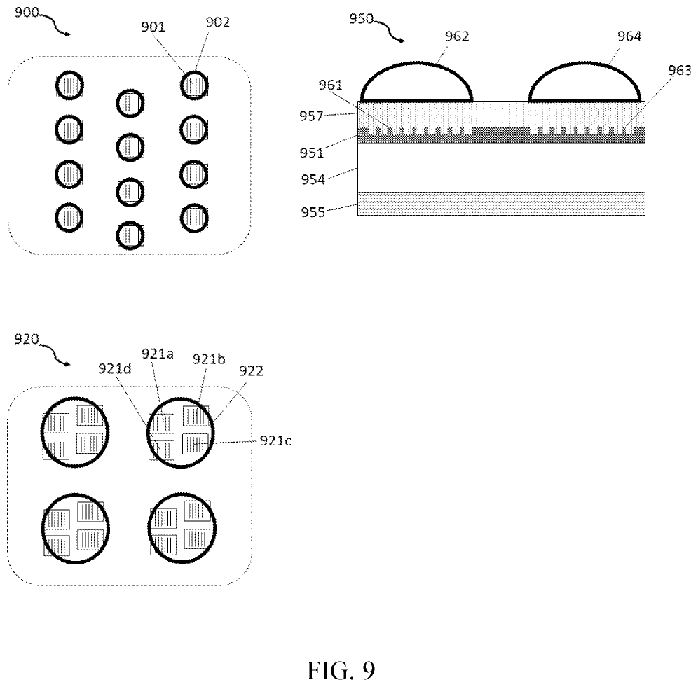

The embodiment shown in FIG. 4 has multiple separate optical sources, four of which are shown but can be any other number. If those optical sources are tuned to different wavelengths or just have low coherence between themselves (owning to each being run separately), the combined coherence of the output beam is reduced significantly. The emitters can be positioned so that those from each optical source are adjacent, or they can be positioned so that emitters of a certain optical source are intermingled with those of a different optical source as explained with the help of FIG. 9 and more specifically view 920. This reduces the spatial coherence of the beam. Low beam coherence is useful in systems where a low-speckle image of the illuminated target is desired.

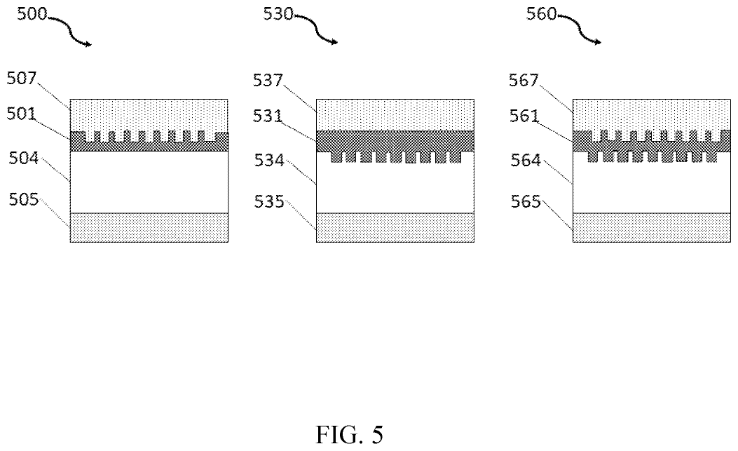

FIG. 5 shows three schematic cross-section views of a component of an integrated photonic device utilizing periodic structures to covert the light from in-plane propagation to out-of-plane propagation. Additional details of particular layers shown in FIG. 5 will be described with the help of FIG. 7, where layers 505, 535 and 565 correspond to layer 705, layers 504, 534 and 564 correspond to layer 704, layers 501, 531 and 561 correspond to layer 701 and layers 507, 537 and 567 correspond to at least one of the layers 703, 707 and 708 in FIG. 7.

Periodic structure shown in view 500 utilizes top side gratings realized in layer 501 to provide out-of-plane light emission where etch depth, duty cycle of the grating and pitch of the grating can be controlled to define the strength and direction of emission. Furthermore, total strength of the grating can also be controlled by the grating length or number of periods.

Periodic structure shown in view 530 utilizes bottom side gratings realized in layer 531/534 to provide out-of-plane light emission where etch depth, duty cycle of the grating and pitch of the grating can be controlled to define the strength and direction of emission. Furthermore, total strength of the grating can also be controlled by the grating length or number of periods. In contrast to view 500, periodic structures as shown in embodiment 530 are realized in layer 534 prior to deposition of layer 531 and as will be described in more details with the help of FIG. 7.

Periodic structure shown in view 560 utilizes both the top and the bottom side gratings realized in layer 561/564 to provide out-of-plane light emission where etch depths, duty cycle of the gratings, offset between top and bottom side gratings and pitch of the gratings can be controlled to define the strength and direction of emission. Furthermore, total strength of the grating can also be controlled by the grating length or number of periods. In contrast to view 500 and 530, periodic structures as shown in embodiment 560 enable additional optimization of the emission pattern due to additional degrees of freedom. In some embodiments, highly unidirectional (e.g. >90% of power goes into one direction) gratings with low back reflection (<−30 dB) can be realized which can be challenging to achieve with designs outlined in views 500 and 530.

All of the above can be used to realize very uniform gratings and/or varying strength gratings as utilized in some embodiments as shown in FIGS. 1-3.

It is obvious to someone skilled in the art that large number of variations in defining the periodic structures are possible, especially if waveguide material can be deposited and re-deposited (as it the case with e.g. SiN). In such cases multiple layers might be utilized as well as other optimizations to facilitate better performance, higher uniformity, and/or higher tolerance to fabrication variation of the emitters.

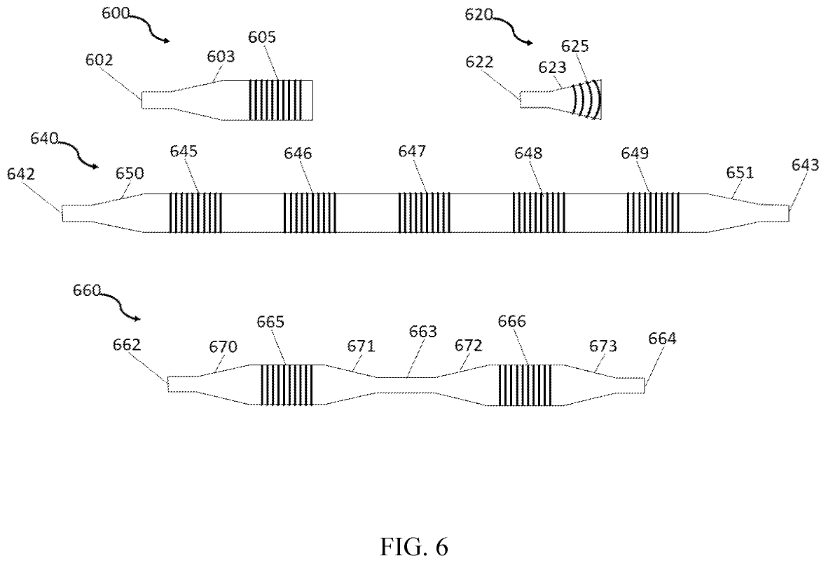

FIG. 6 shows four schematic top views of a component or multiple components of an integrated photonic device utilizing periodic structures to covert the light from in-plane propagation to out-of-plane propagation.

View 600 illustrates an embodiment of a grating that can be utilized in embodiments that utilize splitter structures (e.g. FIG. 1) in which input waveguide 602 is tapered using an adiabatic transition 603 to wider waveguide which comprises the grating structure 605. Grating structure can be realized in one of the embodiments as shown in FIG. 5 or other types of embodiments that enable periodic structures to interact with guided mode. Both the width and the strength of the grating (defining effective length) are used to shape the beam size from the emitter.

View 620 illustrates an embodiment of a grating that can be utilized in embodiments that utilize splitter structures (e.g. FIG. 1) in which input waveguide 622 is tapered using an transition 623 that comprises curved grating structure 625. The use of curved gratings enables size reduction of the whole structure compared to view 600, as the tapered structure does not have to be adiabatic. The advantage of this structure becomes specifically important when widths of the emitter have to be large compared to the input waveguide width, as then length requirements for adiabatic transformation become excessive. The effective width of the grating can be controlled by offsetting the first curved grating from the input, while the effective length is controlled by the strength of the grating, and both can be used to shape the beam size from the emitter. Lastly the width of the input waveguide connecting to tapered transition 623 can control the diffraction of the optical wave as additional knob to control the emitter pattern.

View 640 illustrates an embodiment of a grating structure that can be utilized in embodiments that utilize in-line emitters (e.g. FIG. 2) in which input waveguide 642 is tapered using an adiabatic transition 650 to wider waveguide which comprises multiple grating structures 645, 646, 647, 648 and 649 before another taper 651 reduces the waveguide width to narrower waveguide 643 after which bends, amplifiers, etc can be introduced. Various number of gratings can be implemented (>2), and for each grating the effective strength can be optimized such that the emitted power is similar or different while providing similar or different beam size. In one embodiment the grating strength increases the further they are from the input waveguide, i.e. grating 649 is stronger than grating 648, and grating 648 is stronger than grating 647, etc. The width of all emitters is the same, owning to the same waveguide width in which gratings are defined. In other embodiments, additional tapers (not shown) can be introduced to change the widths of each in-line emitter individually.

View 660 illustrates an embodiment of a grating structure that can be utilized in embodiments that utilize in-line emitters (e.g. FIG. 2) in which input waveguide 662 is tapered using an adiabatic transition 670 to wider waveguide in which first grating 665 is defined. After grating 665, another taper 671 is introduced to reduce the waveguide width to narrower waveguide 663 after which another taper 672 increases the waveguide width before another grating 666, after which width is yet again reduced in taper 673 to output waveguide 664. In this approach, compared to view 640, the reduction of width between individual emitters helps with filtering potentially induced higher order modes that could impact the far-field pattern. View 640 lacks such filtering, but is generally more compact as there are less taper structures compared to embodiment shown in view 660.

It is obvious that various other combinations of emitters, tapers and waveguides can be envisioned without departing from the spirit of invention, and embodiments here only teach a few representative examples.

FIG. 7 is a schematic cross-section view of an integrated photonic device 700 utilizing butt-coupling for efficient coupling between dissimilar materials where one material provides the core of the (passive) waveguide 702, while other layer 701 comprises what is commonly called active device supporting light generation, amplification, detection, and/or modulation. The integration of actives and passives in some embodiments of integrated illuminator are realized in this way.

The exemplary cross-section includes a substrate 705 that can be any suitable substrate for semiconductor and dielectric processing, such as Si, InP, GaAs, quartz, sapphire, glass, GaN, silicon-on-insulator and/or other materials known in the art. In the shown embodiment, a layer of second material 704 is deposited, grown, transferred, bonded or otherwise attached to the top surface of substrate 705 using techniques known in the field. The main purpose of layer 704 is to provide optical cladding for material 702 (to be described in more detail below), if necessary to form an optical waveguide. Optical waveguides are commonly realized by placing higher refractive index core between two lower refractive index layers to confine the optical wave. In some embodiments, layer 704 is omitted and substrate 705 itself serves as a cladding.

Layer 702 is deposited, grown, transferred, bonded or otherwise attached to the top of layer 704 if present, and/or to the top of substrate 705, using techniques known in the field. The refractive index of layer 702 is higher than the refractive index of layer 704 if present, or, if layer 704 is not present, the refractive index of layer 702 is higher than the refractive index of substrate 705. In one embodiment, the material of layer 702 may include, but is not limited to, one or more of SiN, SiNOₓ, TiO₂, Ta₂O₅, (doped) SiO₂, LiNbO₃ and AlN, characterized by bandgap greater than 1.2 eV. In some embodiments, other common dielectric materials may be used for layer 702. In other embodiments, a high-bandgap semiconductor material may be used for layer 702, such as e.g. GaN, InGaP or AlGaAs. In yet other embodiments, other semiconductor materials such as Si can be utilized. In some embodiments refractive index of layer 702 is between 1.44 and 2.5. Either or both of layers 704 and 702 can be patterned, etched, or redeposited to tailor their functionality (define waveguides, splitters, couplers, gratings and other passive components) as is common in the art.

Layer 708, whose refractive index is lower than the refractive index of layer 702, overlays layer 702 and underlays layers 701 and 703, and serves to planarize the patterned surface of layer 702. In some embodiments, the planarity of the top surface of layer 708 is provided by chemical mechanical polishing (CMP) or other etching, chemical and/or mechanical polishing methods. In other embodiments, the planarity is provided because of the intrinsic nature of the method by which layer 708 is deposited, for example if the material of layer 708 is a spin-on glass, polymer, photoresist or other suitable material. The planarization may be controlled to leave a layer of desired, typically very low, thickness on top of the layer 702 (as shown in FIG. 7), or to remove all material above the level of the top surface of the layer 702 (not shown). In the case layer 708 is left on top of layer 702, the target thicknesses are in the range of 10 nm to several hundreds of nm, with practical thickness includes the typical across wafer non-uniformity of the planarization process. In some embodiments, spin-on material is used to planarize and is then etched back resulting with improved across wafer uniformity compared to typical CMP processes.

Layer 701 is bonded (attached) on top of the whole or part of the corresponding (708, 702) top surface. Said bonding can be direct molecular bonding or can use additional materials to facilitate bonding such as e.g. metal layers or polymer films as is known in the art. Layer 701 makes up what is commonly called an active device, and may be made up of materials including, but not limited to, InP and InP-based ternary and quaternary materials, GaAs and GaAs based ternary and quaternary materials, GaN and GaN based ternary and quaternary materials, GaP, InAs and InSb and their variations and derivatives or any other suitable material for providing direct optical emission. Layer 701 in some embodiment is multilayered, comprising sublayers providing both optical and electrical confinement as well as electrical contacts, as is known in the art for active devices. Sublayers of layer 701 in some embodiments provide vertical confinement (up/down in FIG. 7), while the lateral confinement (surface normal to the cross-section shown in FIG. 7) and the facet toward layers 706 (if present) and/or layer 703 are provided by at least one etch, after attachment of layer 701, as is known in the art for active devices.

In some embodiments, layer 701 can be efficiently electrically pumped to generate optical emission and gain. In other embodiments, layer 701 can provide modulation and/or detection functionality. The present invention enables efficient optical coupling between waveguides formed in layer 701 and waveguide whose core is formed in layer 702. Said materials 702 can provide additional functionality such as low propagation loss, wide-band transparency, high intensity handling, combining, splitting, and filtering of light, out-of-plane emission, non-linear generation and/or others as is known in the art.

Efficient coupling is facilitated by layer 703, and, in cases where layer 706 is present, by layer 706. Optional layer 706 primarily serves as either an anti-reflective or a highly-reflective coating at the interface between layer 701 and layer 703. Layer 703 serves as an intermediate waveguide that in some embodiments accepts the profile (depicted by line 750) of an optical mode supported by the waveguide for which layer 701 provides the core, captures it efficiently as mode profile 751, and gradually transfers it to mode profiles 752, and finally 753. Mode profile 753 is efficiently coupled to the waveguide for which layer 702 provides the core.

Layer 703 dimensions and refractive index can be engineered to facilitate efficient butt-coupling of mode profile 750 and to efficiently transform the mode to one with mode profile 753 by taking advantage of tapered structures made in at least one of the layers 702 and 703. In some embodiments, refractive index of layer 703 is smaller than the refractive index of layer 702. In some embodiments the refractive index of layer 703 is between 1.44 and 2.2. Thickness of layer 103 is an optimization parameter, and in some embodiments it is between 400 nm and 4000 nm, thickness largely being dependent on details of the layer 701 design and position and shape of the mode 750. The use of intermediate layer 703 significantly improves efficient transfer between high refractive index materials (such as e.g. III/V materials or similar in layer 701) to lower refractive index materials (such as e.g. SiN in layer 702).

The transformation from mode 751 to mode 753 utilizes adiabatic tapering between the two layers 702 and 703, with a dominant transition happening when there is phase matching between the mode dominantly residing in layer 702 and the mode dominantly residing in layer 703. As this phase matching can be engineered to happen at relatively large waveguide widths, the need for very fine taper tips can be fully removed. In some cases, tapers as wide as e.g. 200 nm or wider can support efficient transmission enabling high fabrication yield even if standard lithography is utilized. In other cases, narrower tapers, e.g. with width approaching 100 nm, can be utilized which can also be fabricated using high-quality DUV lithography enabling high-throughput fabrication.

Differences between the optical modes supported by waveguides in layers 701 and 702 respectively may or may not be obvious by observation of the mode profiles, but mode overlaps less than 100% and vertical offset (in FIG. 7) between modes 750 and 753 could (in the absence of intermediate layer 703) result in significant optical loss. In some cases, it may be considered that losses of up to 2 dB are acceptable, but losses greater than that are not. In other cases, a 5 dB loss level may be the criterion chosen. The function of layer 703 is to keep optical coupling loss due to imperfect mode overlap and vertical offset (between modes 750 and 753) below whatever is determined to be an acceptable level in a given application.

The upper cladding layer 707 for waveguides realized in 703 and/or 702 can be ambient air (meaning no cladding material is actually deposited) or can be any other deliberately deposited suitable material as shown in FIG. 7, including, but not limited to, a polymer, SiO2, SiN, SiNOx etc. In some embodiments same material is used for layer 707 and layer 708. In some embodiments (not shown), layer 707 cladding functionality can be provided with multiple depositions, e.g. one material provides the cladding for mode 753 guided by core formed in layer 702, and another material provides the cladding for mode 751 guided by core formed in layer 703. In yet another embodiment (not shown), layer 703 can provide cladding functionality to layer 702 and mode 753 in at least part of the structure.

One or more lithography alignment marks (not shown in this cross-sectional view, but see, for example, 140 in FIG. 1) are present to facilitate precise alignment between the layers formed during various processing steps. This alignment using photolithography and common alignment marks enables fast and efficient bonding of layer 701, as no fine alignment is needed in this step while extreme precision (down to the resolution of the stepper tool which can be <100 nm for deep-ultraviolet tools) is provided during subsequent semiconductor processing.

FIG. 8 shows four schematic top views of embodiments of a component of an integrated photonic device providing optical source functionality.

View 800 illustrates an embodiment of an optical source realized as an Fabry-Perot laser 802 with mirrors defined at III/V facets and coupled to passive waveguide 805 as described with the help of FIG. 7.

View 820 illustrates an embodiment of an optical source realized as an Fabry-Perot laser 822 with at least one mirror partly defined as loop mirror 828 in passive waveguide and one mirror at least partly defined at III/V facet and coupled to passive waveguide 825 as described with the help of FIG. 7.

View 840 illustrates an embodiment of an optical source realized as a grating 848 stabilized laser 842 with at least one mirror partly defined at III/V facet and coupled to passive waveguide 845 as described with the help of FIG. 7. The benefit of grating stabilized laser is the reduced output wavelength sensitivity to temperature. If the grating 848 is defined in e.g. SiN it has significantly lower temperature coefficient of the refractive index (dn/dT) compared to e.g. gain peak temperature dependency of common active materials (that would primarily define the lasing wavelength of an Fabry-Perot laser). This can significantly reduce the change in the output wavelength as a function of temperature which can improve the system performance in at least following ways: (1) control of the output pattern which can be wavelength sensitive if realized with periodic structures and (2) control of the output wavelength and corresponding pattern that is detected with a camera utilizing band-pass filters. In case output wavelength drifts too much, the output wavelength can go outside the transparency range of the band-pass filter reducing the detected signal and performance of the system as will be described in more details below. The same issue can arise in systems which use propagation through atmospheric systems which may have wavelength-dependent loss due to molecular absorption, various scattering mechanisms or other effects.

View 860 illustrates an embodiment of an optical source realized as a widely tunable laser 862 with at least one mirror partly defined as tunable frequency selective loop mirror 868 in passive waveguide with other mirror at least partly defined either as loop mirror (similar to view 820) or at least partly defined as III/V facet and coupled to passive waveguide 865 as described with the help of FIG. 7. This arrangement enables wide tuning of the output wavelength, allowing to effectively compensate any drift in the output wavelength of the optical source by controlling the tunable frequency selective loop mirror 868 as is known in the art of ring-resonator based tunable lasers.

FIG. 9 shows two schematic top views and one schematic cross-section view of embodiments of emitter component of an integrated photonic device. In some embodiments, external lenses are utilized to shape and collimate the beams from individual emitters as shown in view 900 where each emitter 901 has a corresponding lens 902 providing beam collimation and shaping. View 920 shows another embodiment of present invention in which multiple emitters, four of which are shown 921a-921d, have one corresponding lens 922. Each of the emitters can be a part of the same or a different sub-unit as described with the help of FIG. 4. It is obvious that number of emitters corresponding to a particular lens can vary from one to generally a large number, as well as that that number can vary for each particular lens in the system. An advantage of utilizing multiple emitters using the same lens can be in the control of speckle, as each sub-unit can be connected to a different optical source reducing the speckle.

In view 950, showing a cross-section view corresponding to the cross-section view as described with the help of view 500 in FIG. 5, the lens is placed above the photonic integrated circuit without a spacer (as shown) or with a spacer (not shown). Lenses can be assembled, microprinted, etched or otherwise fabricated and accordingly positioned in regards to emitter elements. Functional layers 951 to 957 (unless explicitly defined differently) correspond to functional layers 501 to 507 as described in relation to FIG. 5. Two (961 and 963) or more emitter structures are defined as periodic structures that interact with the optical signal propagating through waveguide whose core is defined in layer 951 and their output is accordingly shaped by two (962 and 964) or more lenses. In other embodiments, not shown in cross-section but described with the help of view 920, two or more emitters are matched to a single lens.

The integrated illuminator can be designed to operate at various wavelengths. In some cases, operation in visible wavelength range is preferred, and optical source in such embodiments can utilize GaN and GaAs based active materials. In other cases, operation in near-visible (e.g. 850 nm, 940 nm, 980 nm) is preferred—in such cases GaAs based active materials can be utilized for the optical source. In yet other embodiments, operation at longer wavelength range can be preferred (e.g. 1380 nm, 1550 nm or similar). In such embodiments InP based active materials can be utilized for the optical source. In yet other embodiments, the active structures are utilizing quantum dots, so operation around 1300 nm can be supported by GaAs based actives. In yet other embodiments, operation at yet longer wavelengths is preferred, such as beyond 2 μm wavelength. In such cases the use of quantum cascade and interband cascade lasers and materials can be preferred. In yet other embodiments, operation at multiple wavelengths might be preferred. In other embodiments, emitters with different wavelengths covering a wide range are preferred, perhaps requiring different active materials. In all cases, the waveguides have to support the full operating wavelength range of the system which is done by selecting appropriate materials that provide low material losses in the wavelength range of interest.

The illuminator PIC may be combined with a lens and/or diffuser system to project a particular image. That image may have each emitter individually focused into dots at the target plane, or may combine the light from all of the emitters together. Intermediate options are also possible, depending on the application.

The integrated illuminator is typically combined with a camera system used to image the projected pattern, and electronics circuitry that controls both the illuminator and the camera. In some embodiments, the integrated illuminator can be operated in a pulsed regime, in some other cases it can be operated in continuous wave regime. In yet other embodiments, the optical source and/or particular output can be modulated either in amplitude, frequency and/or phase for additional functionality including more precise measurement of distances. In some embodiments, detection can utilize the on-chip photodetectors as described with the help of FIGS. 1-3, i.e. there is no camera system. A typical use of such system would be proximity sensing and/or distance measurement. A typical use of integrated illuminator as paired with a camera system is the depth perception and space mapping, which can be beneficial in multiple applications. To improve the performance of the system, camera can include a band-pass filter to keep out other signals from saturating the individual detection elements (e.g. sunlight) and improve the signal to noise of the complete system. In general, it is beneficial that the band-pass filter is narrow, but in cases of very narrow filters—wavelength output stabilization techniques for the optical source might have to be utilized. Some of such approaches are described with the help of FIG. 8.

It is to be understood that these illustrative embodiments teach just several examples of heterogeneously integrated illuminators utilizing present invention and many similar arrangements can be further envisioned. Furthermore, such illuminators can be combined with multiple other components to provide additional functionality or better performance such as various filtering elements, amplifiers, monitor photodiodes, modulators and/or other photonic components.

Embodiments of the present invention offer many benefits. The integration platform enables scalable manufacturing of PICs made from multiple materials providing higher-performance and/or ability to operate in broadband wavelength range. Furthermore, the platform is capable of handling high optical power compared to typical Si waveguide-based or InP waveguide-based PICs.

This present invention utilizes a process flow consisting of typically wafer-bonding of a piece of compound semiconductor material on a carrier wafer with dielectric waveguides (as is described with the help of FIG. 7) and subsequent semiconductor fabrication processes as is known in the art. It enables an accurate definition of optical alignment between active and passive waveguides via typically photo lithography step, removing the need for precise physical alignment. Said photo lithography-based alignment allows for scalable manufacturing using wafer scale techniques.

It is to be understood that optical coupling between modes in active and passive layers is reciprocal, so that, taking FIG. 7 as exemplary, the structure can be configured to facilitate light transmission from region 701 to region 702, but also to facilitate transmission in the reverse direction, from region 702 to region 701. It is to be understood that multiple such transitions with no limitation in their number or orientation can be realized on a suitably configured PIC.

Other approaches have relied on die attachment of pre-fabricated optical active devices to passive waveguides. This requires very stringent alignment accuracy which is typically beyond what a typical die-bonder can provide. This aspect limits the throughput of this process as well as the performance of optical coupling.

In some embodiments the active device can utilize the substrate for more efficient thermal sinking, due to direct contact to the substrate with no dielectric in-between.

In some embodiments, the active device creates a hybrid waveguide structure with dielectric layers which can be used, for example, to create a wavelength selective component formed inside the laser cavity for e.g. distributed feedback (DFB) lasers or similar components.

Embodiments of the optical devices described herein may be incorporated into various other devices and systems including, but not limited to, various computing and/or consumer electronic devices/appliances, industrial systems, communication systems, medical devices, sensors and sensing systems and other areas that can benefit from small size illuminators.

It is to be understood that the disclosure teaches just few examples of the illustrative embodiment and that many variations of the invention can easily be devised by those skilled in the art after reading this disclosure and that the scope of the present invention is to be determined by the following claims.

1. A device comprising:
at least one of first, second and third elements fabricated on a common substrate;
wherein at least one of the first elements comprises an active waveguide structure supporting an active optical mode, at least one of the second elements comprises a passive waveguide structure supporting a passive optical mode, and at least one of the third elements, at least partly butt-coupled to at least one of the first elements, comprises an intermediate waveguide structure supporting intermediate optical modes;
wherein at least one of the first elements comprises an optical source;
wherein the first element active waveguide structure is defined by at least one etch after attachment to the common substrate;
wherein at least one of the second elements comprises at least one splitter structure and at least one of the second elements comprises at least two emitter structures; and
wherein mutual alignments of the first, second and third elements are defined using lithographic alignment marks that facilitate precise alignment between layers formed during processing steps of fabricating the first, the second and the third elements on a common substrate.

2. A device of claim 1,
wherein at least one of the second elements further comprises at least one tap coupler and at least one of the first elements further comprises at least one photodetector.

3. A device of claim 1,
wherein the emitter structures are defined as periodic structures.

4. A device of claim 1,
wherein the optical source is wavelength stabilized.

5. A device of claim 1,
wherein at least one of the first elements comprises at least one semiconductor optical amplifier.

6. A device of claim 1,
wherein at least two emitter structures are optically coupled to at least two lenses.

7. A device of claim 1,
wherein at least one emitter structure in at least one of the second elements is configured to receive incident light and couple it to at least one photodetector in at least one of the first elements.

8. A device of claim 1,
wherein at least one of the first elements or at least one of the second elements comprises at least one tuning element configured to control at least one of an amplitude or a phase of a signal.

9. A device comprising:
at least one of first, second and third elements fabricated on a common substrate;
wherein at least one of the first elements comprises an active waveguide structure supporting an active optical mode, at least one of the second elements comprises a passive waveguide structure supporting a passive optical mode, and at least one of the third elements, at least partly butt-coupled to at least one of the first elements, comprises an intermediate waveguide structure supporting intermediate optical modes;
wherein at least one of the first elements comprises an optical source;
wherein the first element active waveguide structure is defined by at least one etch after attachment to the common substrate;
wherein at least one of the second elements comprises at least two in-line emitter structures; and
wherein mutual alignments of the first, second and third elements are defined using lithographic alignment marks that facilitate precise alignment between layers formed during processing steps of fabricating the first, the second and the third elements on a common substrate.

10. A device of claim 9,
wherein at least one of the second elements further comprises at least one tap coupler and at least one of the first elements further comprises at least one photodetector.

11. A device of claim 9,
wherein the emitter structures are defined as periodic structures.

12. A device of claim 9,
wherein the optical source is wavelength stabilized.

13. A device of claim 9,
wherein at least one of the first elements comprises at least one semiconductor optical amplifier.

14. A device of claim 9,
wherein at least two emitter structures are optically coupled to at least two lenses.

15. A device of claim 9,
wherein at least one emitter structure in in at least one of the second elements is configured to receive incident light and couple it to at least one photodetector in at least one of the first elements.

16. A device of claim 9,
wherein at least one of the first elements or at least one of the second elements comprises at least one tuning element configured to control at least one of an amplitude or a phase of a signal.
